(19) United States
(12) Patent Application Publication
(10) Pub. No.: US 2014/0374870 A1
(43) Pub. Date: Dec. 25, 2014

(54) IMAGE SENSOR MODULE AND METHOD OF MANUFACTURING THE SAME

(71) Applicant: Samsung Electro-Mechanics Co., Ltd., Suwon-si (KR)

(72) Inventors: Kyung Ho Lee, Suwon-si (KR); Suk Jin Ham, Suwon-si (KR); Seung Wan Woo, Suwon-si (KR); Yee Na Shin, Suwon-si (KR)

(73) Assignee: SAMSUNG ELECTRO-MECHANICS CO., LTD., Suwon-si (KR)

(21) Appl. No.: 14/170,325

(22) Filed: Jan. 31, 2014

(30) Foreign Application Priority Data
Jun. 19, 2013 (KR) 10-2013-0070598

(51) Int. Cl. H01L 27/146

(52) U.S. Cl. CPC H01L 27/14618; H01L 27/14625
USPC 257/466; 438/64

(57) ABSTRACT

Disclosed herein are an image sensor module and a method of manufacturing the same. The image sensor includes: a base substrate having an image sensor mounted groove including a first groove and a second groove having a stepped shape; and an image sensor mounted in a groove of the base substrate.

### CROSS REFERENCE TO RELATED APPLICATION

This application claims the benefit of Korean Patent Application No. 10-2013-0070598, filed on Jun. 19, 2013, entitled “Image Sensor Module And Method Of Manufacturing for The Same” which is hereby incorporated by reference in its entirety into this application.

### BACKGROUND OF THE INVENTION

1. Technical Field

The present invention relates to an image sensor module and a method of manufacturing the same.

2. Description of the Related Art

An image sensor module, which has a form in which an image sensor is attached on a substrate by using a die attach bond, needs to be manufactured so that the image sensor is exactly vertical to a lens.

However, at the time of manufacturing the image sensor module, since a process of dispensing a fluid-state die attach bond having viscosity to the substrate and then disposing the image sensor thereon and a thermal process of hardening the bond need to be performed, it may be difficult to manufacture the image sensor module so that the image sensor is exactly vertical to the lens, that is, the image sensor is exactly vertical to the substrate.

### PRIOR ART DOCUMENT

### Patent Document

(Patent Document 1) US Patent Laid-Open Publication No. 2011-0317392

### SUMMARY OF THE INVENTION

The present invention has been made in an effort to provide an image sensor module having double grooves facing each other disposed outside a lower portion of an image sensor and a method of manufacturing the same.

According to a preferred embodiment of the present invention, there is provided an image sensor module, including: a base substrate having an image sensor mounted groove including a first groove and a second groove having a stepped shape; and an image sensor mounted in a groove of the base substrate.

The image sensor may be surface-bonded with the first groove and the second groove may be filled with an adhesive.

The second groove may have a cross shape.

The first groove may be made of metal.

A plane shape of the groove may correspond to a plane shape of a lower portion of the image sensor.

The second groove may have a protrusion protruding to an outside of the mounted image sensor.

According to another preferred embodiment of the present invention, there is provided a method of manufacturing an image sensor module, including: preparing an image sensor mounted base substrate including a first groove and a second groove having a stepped shape; applying an adhesive in the image sensor mounted groove; and mounting the image sensor on the base substrate to which the adhesive is applied.

The forming of the image sensor mounted groove may include: preparing a base substrate; machining a primary groove on the base substrate by a laser trimming process; and forming an image sensor mounted groove having a first groove and a second groove having a stepped shape by secondarily machining the primary groove by an etching process.

The forming of the image sensor mounted groove may include: preparing a base substrate; machining a primary groove on the base substrate by a photolithography process; and forming an image sensor mounted groove having a first groove and a second groove having a stepped shape by secondarily machining the primary groove by an etching process.

The forming of the image sensor mounted groove may include: preparing a base substrate; preparing an insulating layer having a cavity; stacking the insulating layer on the base substrate; and forming an image sensor mounted groove having the first groove and the second groove having a stepped shape by etching a cavity region of the base substrate on which the insulating layer is stacked.

The second groove may have a cross shape.

The first groove may be made of metal.

A plane shape of the groove may be formed to correspond to a plane shape of a lower portion of the image sensor.

The second groove may have a protrusion protruding to an outside of the mounted image sensor.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a three-dimensionally exemplified diagram of a base substrate according to a preferred embodiment of the present invention;

FIG. 2 is a three-dimensionally exemplified diagram of a structure of an image sensor module according to a preferred embodiment of the present invention;

FIG. 3 is a cross-sectional view of the structure of the image sensor module according to the preferred embodiment of the present invention;

FIG. 4 is a three-dimensionally exemplified diagram of a base substrate according to another preferred embodiment of the present invention;

FIG. 5 is a three-dimensionally exemplified diagram of a structure of an image sensor module according to another preferred embodiment of the present invention;

FIG. 6 is a cross-sectional view of a structure of an image sensor module according to another preferred embodiment of the present invention;

FIG. 7 is a three-dimensionally exemplified diagram of a base substrate according to another preferred embodiment of the present invention;

FIG. 8 is a three-dimensionally exemplified diagram of a structure of an image sensor module according to another preferred embodiment of the present invention;

FIG. 9 is a cross-sectional view of a structure of an image sensor module according to another preferred embodiment of the present invention;

FIGS. 10 to 13 are process flow charts according to a method of manufacturing an image sensor module according to a first preferred embodiment of the present invention;

FIGS. 14 to 18 are process flow charts according to a method of manufacturing an image sensor module according to a second preferred embodiment of the present invention;

FIGS. 19 to 22 are process flow charts according to a method of manufacturing an image sensor module according to a third preferred embodiment of the present invention;

FIGS. 23 to 27 are process flow charts according to a method of manufacturing an image sensor module according to a fourth preferred embodiment of the present invention;

FIGS. 28 to 31 are process flow charts according to a method of manufacturing an image sensor module according to a fifth preferred embodiment of the present invention; and

FIGS. 32 to 36 are process flow charts according to a method of manufacturing an image sensor module according to a sixth preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the accompanying drawings.

Image Sensor Module

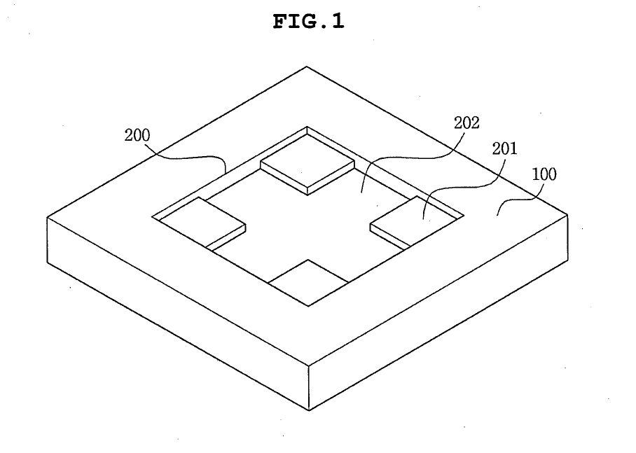

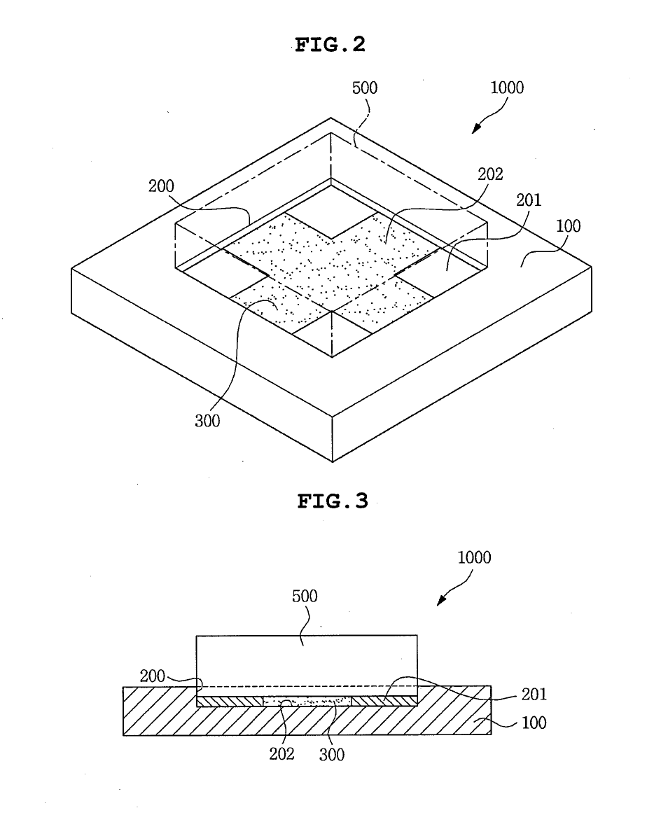

FIGS. 1 and 2 are three-dimensionally exemplified diagrams of a structure of an image sensor module according to a preferred embodiment of the present invention.

FIG. 1 is a three-dimensionally exemplified diagram of a base substrate 100 having an image sensor mounted groove 200 including a first groove 201 and a second groove 202 having a stepped shape.

As illustrated in FIG. 2, an image sensor module 1000 includes a base substrate 100 having the image sensor mounted groove 200 including the first groove 201 and the second groove 202 having a stepped shape and an image sensor 500 mounted in the groove of the base substrate 100.

The base substrate 100 may be a printed circuit board, a ceramic substrate, a metal substrate having an anodized layer, and the like, but is not particularly limited thereto.

The base substrate 100, which is a circuit board on which at least one layer of circuit including a connection pad is formed on an insulating layer thereof, may be a printed circuit board. For convenience of explanation, FIG. 1 does not illustrate a detailed configuration of an inner layer circuit, but it may be sufficiently recognized by those skilled in the art that as the base substrate 100, a general circuit board on which at least one layer of circuit is formed on the insulating layer may be used.

As the insulating layer, a resin insulating layer may be used. As a material of the resin insulating layer, a thermo-setting resin such as an epoxy resin, a thermo-plastic resin such as a polyimide resin, a resin having a reinforcement material such as a glass fiber or an inorganic filler impregnated in the thermo-setting resin and the thermo-plastic resin, for example, a prepreg may be used. In addition, a thermo-setting resin, a photo-curable resin, and the like, may be used. However, the material of the resin insulating layer is not particularly limited thereto.

In addition, the circuit including the connection pads may be made of any material used as a conductive metal for a circuit in a circuit board field, and is typically made of copper in the case of a printed circuit board.

The ceramic substrate may be made of metal based nitride or a ceramic material. Here, the metal based nitride may include aluminum nitride (AlN) or silicon nitride (SiN) and the ceramic material may include aluminum oxide (Al₂O₃) or beryllium oxide (BeO), but are not particularly limited thereto.

Meanwhile, the metal substrate may be made of, for example, aluminum (Al) which is a metal material capable of being easily obtained at a relatively low cost and has significantly excellent heat transfer characteristics, or an alloy thereof.

In addition, the anodized layer which is formed by immersing the metal substrate made of aluminum or an alloy thereof in an electrolyte solution such as boric acid, phosphoric acid, sulfuric acid, chromic acid, or the like, and then applying an anode to the metal substrate and applying a cathode to the electrolyte solution, has insulation characteristics and relatively high heat transfer characteristics of about 10 to 30 W/mk.

As described above, the anodized layer made of aluminum or an alloy thereof may be an aluminum anodized layer (Al₂O₃).

Since the anodized layer has insulation characteristics, it enables a circuit layer to be formed on the base substrate 100. In addition, since the anodized layer may be formed at a thickness thinner than that of a general insulation layer, it enables thinness simultaneously with further improving heat radiating performance.

In this case, the first groove 201 of the base substrate 100 having the image sensor mounted groove may be surface-bonded with a lower portion of the image sensor 500.

Further, the first groove 201 is made of a material having high thermal conductivity, for example, metal and the image sensor 500 may directly contact a surface of the first groove 201 to expect an effect of discharging heat generated during an operation.

Further, in order to attach the base substrate 100 to the image sensor 500, an adhesive 300 may be interposed in the second groove 202.

In this case, the second groove 202 may have a cross shape, but is not particularly limited thereto.

Further, referring to FIG. 2, a plane shape of the groove 200 may correspond to a plane shape of the lower portion of the image sensor 500.

That is, the image sensor 500 on the adhesive 300 interposed in the second groove 202 is disposed in the groove 200 corresponding to the plane shape thereof to prevent warpage and distortion, thereby expecting the effect of improving the optical performance of the image sensor module.

FIG. 3 is a cross-sectional view of the image sensor module 1000 which includes the base substrate 100 having the image sensor mounted groove 200 including the first groove 201 and the second groove 202 having a stepped shape and the image sensor 500 mounted in the groove of the base substrate 100.

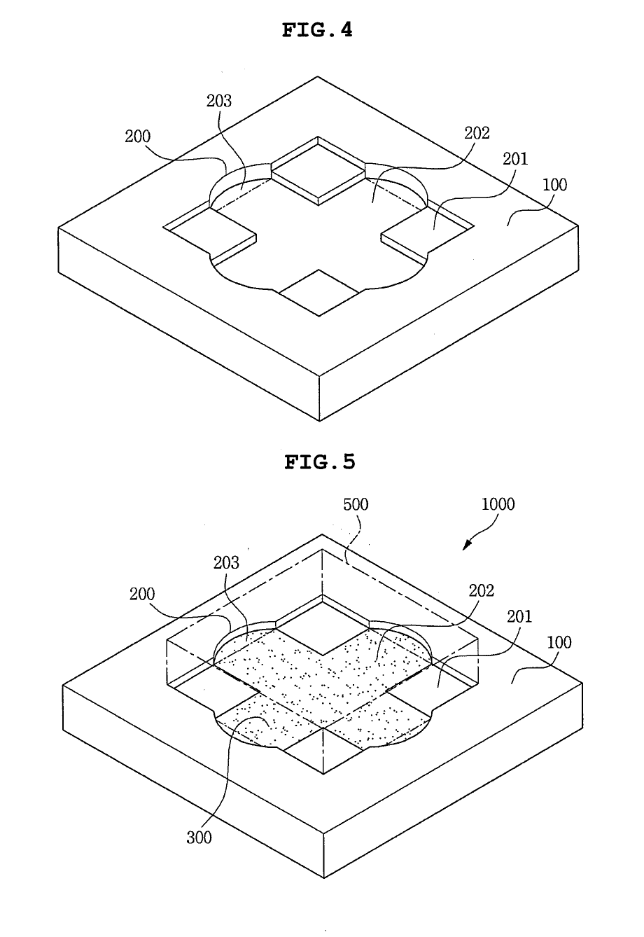

FIGS. 4 and 5 are three-dimensionally exemplified diagrams of a structure of an image sensor module according to another preferred embodiment of the present invention.

FIG. 4 is a three-dimensionally exemplified diagram of the base substrate 100 having an image sensor mounted groove 200 including a first groove 201 and a second groove 202 having a stepped shape and including a protruding region 203 on the second groove 202.

As illustrated in FIG. 5, the image sensor module 1000 includes the base substrate 100 having the image sensor mounted groove 200 including the first groove 201 and the second groove 202 having a stepped shape and the protruding region 203 on the second groove 202 and the image sensor 500 mounted in the groove of the base substrate 100.

In this case, the protruding region 203 may have a form protruding to the outside of the mounted image sensor 500.

Further, the first groove 201 of the base substrate 100 having the image sensor mounted groove may be surface-boned with the lower portion of the image sensor 500.

Further, the first groove 201 is made of a material having high thermal conductivity, for example, metal and the image sensor 500 may directly contact the surface of the first groove 201 to expect an effect of discharging heat generated during an operation.

Further, in order to attach the base substrate 100 to the image sensor 500, an adhesive 300 may be interposed in the second groove 202.

The adhesive 300 applied in the second groove 202 may move to the protruding region 203 when the image sensor 500 contacts the surface of the first groove 201.

This is a space to prevent the adhesive 300 from overflowing to the outside of the groove 200, thereby improving the reliability of the image sensor module.

In this case, the second groove 202 may have a cross shape, but is not particularly limited thereto.

Further, referring to FIG. 5, except for the protruding region 203, the plane shape of the groove 200 may correspond to the plane shape of the lower portion of the image sensor 500.

That is, the image sensor 500 on the adhesive 300 interposed in the second groove 202 is disposed in the groove 200 corresponding to the plane shape thereof to prevent warpage and distortion, thereby expecting the effect of improving the optical performance of the image sensor module.

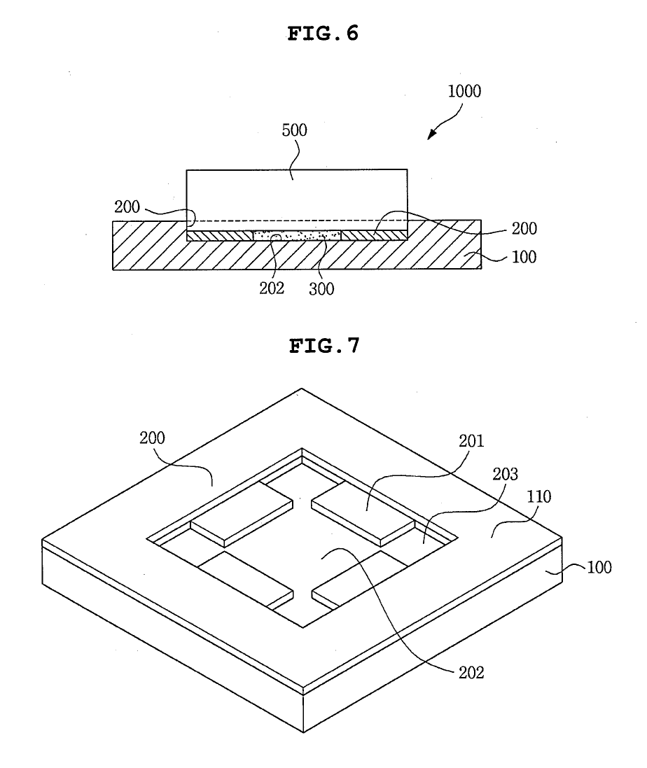

FIG. 6 is a cross-sectional view of the image sensor module 1000 which includes the base substrate 100 having the image sensor mounted groove 200 including the first groove 201 and the second groove 202 having a stepped shape and the image sensor 500 mounted in the groove of the base substrate 100.

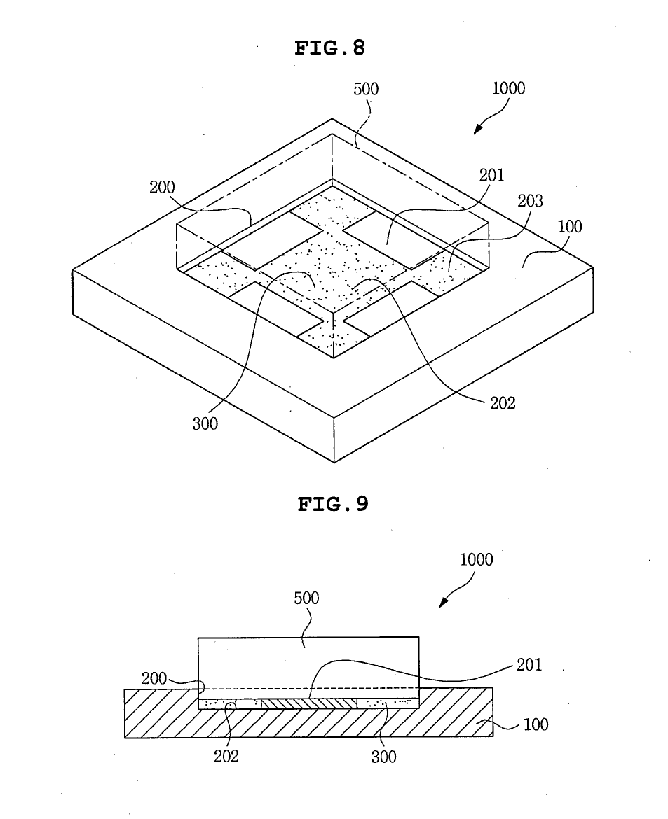

FIGS. 7 and 8 are three-dimensionally exemplified diagrams of a structure of an image sensor module according to another preferred embodiment of the present invention.

FIG. 7 is a three-dimensionally exemplified diagram of the base substrate 100 having an image sensor mounted groove 200 including a first groove 201 and a second groove 202 having a stepped shape and including a protruding region 203 on the second groove 202.

As illustrated in FIG. 8, the image sensor module 1000 includes the base substrate 100 having the image sensor mounted groove 200 including the first groove 201 and the second groove 202 having a stepped shape and the protruding region 203 on the second groove 202 and the image sensor 500 mounted in the groove of the base substrate 100.

In this case, the protruding region 203 may have a form in which it does not protrude to the outside of the mounted image sensor 500.

Further, the first groove 201 of the base substrate 100 having the image sensor mounted groove may be surface-bonded with the lower portion of the image sensor 500.

Further, the first groove 201 is made of a material having high thermal conductivity, for example, metal and the image sensor 500 may directly contact a surface of the first groove 201 to expect an effect of discharging heat generated during an operation.

Further, in order to attach the base substrate 100 to the image sensor 500, an adhesive 300 may be interposed in the second groove 202.

The adhesive 300 applied in the second groove 202 may move to the protruding region 203 when the image sensor 500 contacts the surface of the first groove 201.

This is a space to prevent the adhesive 300 from overflowing to the outside of the groove 200, thereby improving the reliability of the image sensor module.

In this case, the second groove 202 may have a quadrangular shape, but is not particularly limited thereto.

Further, referring to FIG. 8, the plane shape of the groove 200 may correspond to the plane shape of the lower portion of the image sensor 500.

That is, the image sensor 500 on the adhesive 300 interposed in the second groove 202 is disposed in the groove 200 corresponding to the plane shape thereof to prevent warpage and distortion, thereby expecting the effect of improving the optical performance of the image sensor module.

FIG. 9 is a cross-sectional view of the image sensor module 1000 which includes the base substrate 100 having the image sensor mounted groove 200 including the first groove 201 and the second groove 202 having a stepped shape and the image sensor 500 mounted in the groove of the base substrate 100.

Method of Manufacturing Image Sensor Module

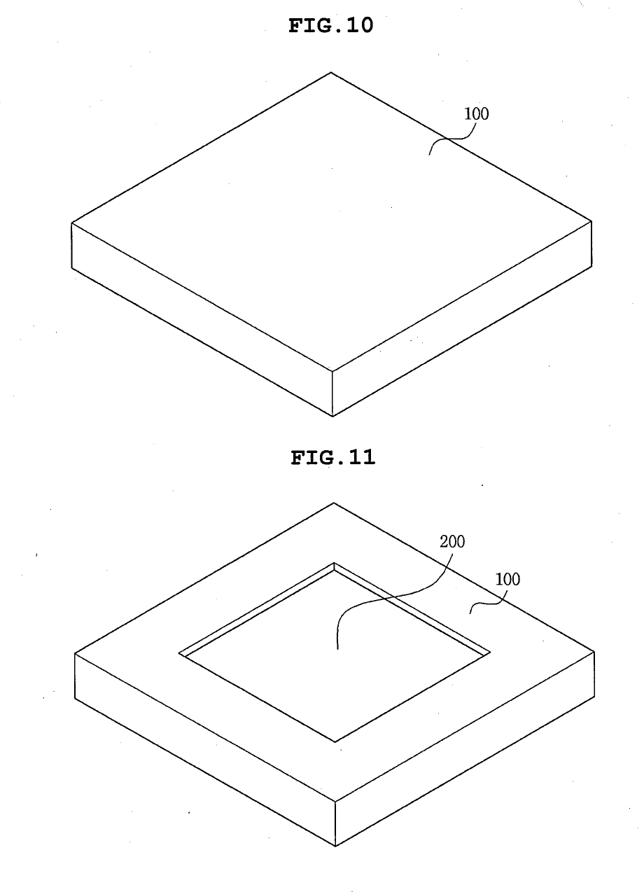

FIGS. 10 to 13 are three-dimensionally exemplified diagrams sequentially illustrating a process of forming the image sensor mounted groove 200 of the base substrate 100 according to a first preferred embodiment of the present invention.

As illustrated in FIG. 10, first, the base substrate 100 is prepared.

The base substrate 100 may be a printed circuit board, a ceramic substrate, a metal substrate having an anodized layer, and the like, but is not particularly limited thereto.

The base substrate 100, which is a circuit board on which at least one layer of circuit including a connection pad is formed on an insulating layer thereof, may be a printed circuit board. For convenience of explanation, FIG. 1 does not illustrate a detailed configuration of an inner layer circuit, but it may be sufficiently recognized by those skilled in the art that as the base substrate 100, a general circuit board on which at least one layer of circuit is formed on the insulating layer may be used.

As the insulating layer, a resin insulating layer may be used. As a material of the resin insulating layer, a thermo-setting resin such as an epoxy resin, a thermo-plastic resin such as a to polyimide resin, a resin having a reinforcement material such as a glass fiber or an inorganic filler impregnated in the thermo-setting resin and the thermo-plastic resin, for example, a prepreg may be used. In addition, a thermo-setting resin, a photo-curable resin, and the like, may be used. However, the material of the resin insulating layer is not particularly limited thereto.

In addition, the circuit including the connection pads may be made of any material used as a conductive metal for a circuit in a circuit board field, and is typically made of copper in the case of a printed circuit board.

The ceramic substrate may be made of metal based nitride or a ceramic material. Here, the metal based nitride may include aluminum nitride (AlN) or silicon nitride (SiN) and the ceramic material may include aluminum oxide (Al₂O₃) or beryllium oxide (BeO), but are not particularly limited thereto.

Meanwhile, the metal substrate may be made of, for example, aluminum (Al) which is a metal material capable of being easily obtained at a relatively low cost and has significantly excellent heat transfer characteristics, or an alloy thereof.

In addition, the anodized layer which is formed by immersing the metal substrate made of aluminum or an alloy thereof in an electrolyte solution such as boric acid, phosphoric acid, sulfuric acid, chromic acid, or the like, and then applying an anode to the metal substrate and applying a cathode to the electrolyte solution, has insulation characteristics and relatively high heat transfer characteristics of about 10 to 30 W/mk.

As described above, the anodized layer made of aluminum or an alloy thereof may be an aluminum anodized layer (Al₂O₃).

Since the anodized layer has insulation characteristics, it enables a circuit layer to be formed on the base substrate 100. In addition, since the anodized layer may be formed at a thickness thinner than that of a general insulation layer, it enables thinness simultaneously with further improving heat radiating performance.

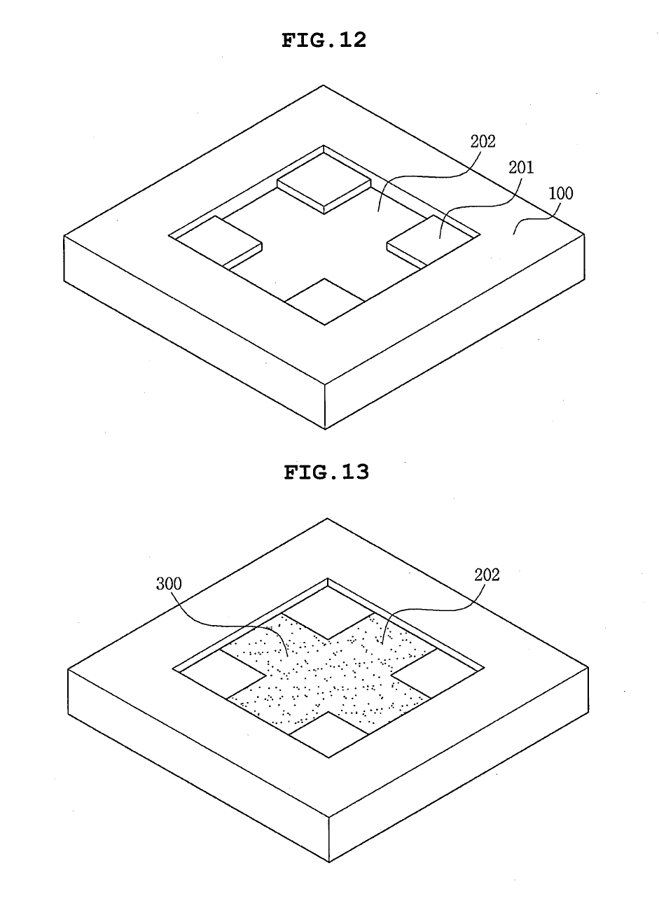

As illustrated in FIG. 11, a first method of machining the image sensor mounted groove 200 on the base substrate 100 may use a laser to perform laser trimming until the groove is generated, thereby forming a primary groove.

Further, as a second method, a photolithography method may be used.

As illustrated in FIG. 12, the machined primary groove may be secondarily machined by an etching method to form the first groove 201 and the second groove 202 having a stepped shape.

Further, the first groove 201 is made of a material having high thermal conductivity, for example, metal and the image sensor 500 may directly contact a surface of the first groove 201 to expect an effect of discharging heat generated during an operation.

In this case, the second groove 202 may have a cross shape, but is not particularly limited thereto.

As illustrated in FIG. 13, the adhesive may be applied in the second groove 202.

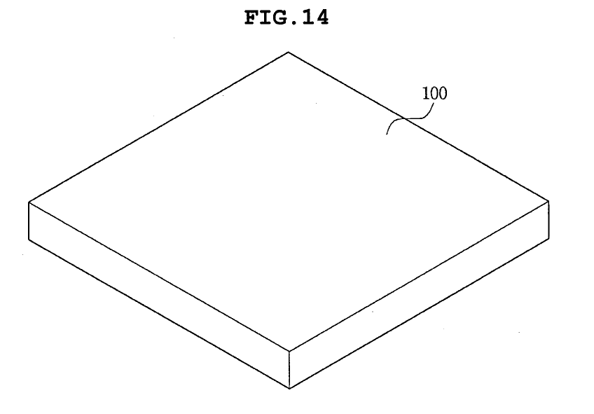

FIGS. 14 to 18 are three-dimensionally exemplified diagrams sequentially illustrating a process of forming the image sensor mounted groove 200 of the base substrate 100 according to a second preferred embodiment of the present invention.

As illustrated in FIG. 14, first, the base substrate 100 is prepared.

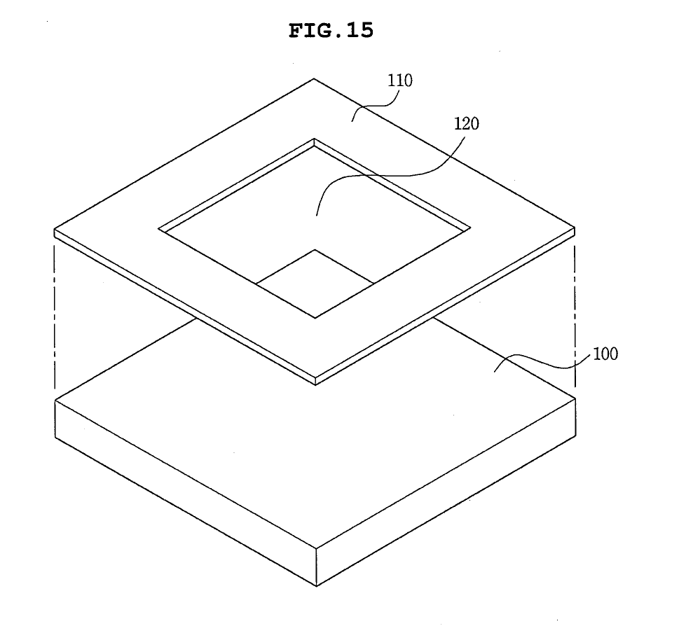

As illustrated in FIG. 15, an insulating layer 110 having a cavity 120 is prepared.

The cavity 120 may be formed by a method of patterning and punching the insulating layer 110.

In this case, a shape of the cavity 120 may be formed to correspond to an outside shape of the lower portion of the image sensor 500.

Further, the insulating layer 110 having the cavity 120 may be stacked on the base substrate 100.

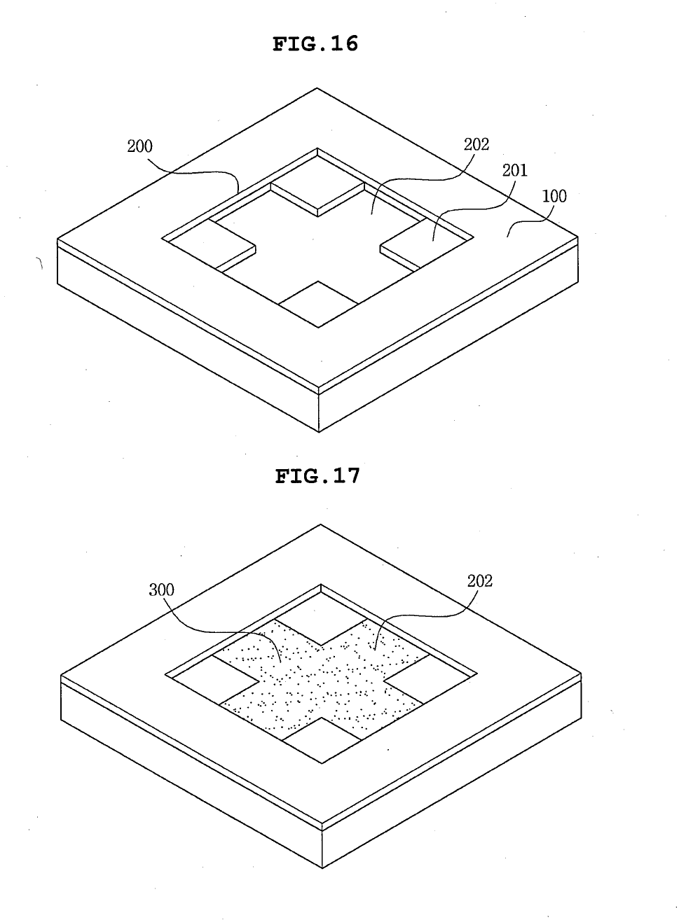

As illustrated in FIG. 16, the cavity 120 region of the stacked base substrate 100 may be machined by the etching method to form the image sensor mounted groove 200 having the first groove 201 and the second groove 202 having a stepped shape.

Further, the first groove 201 is made of a material having high thermal conductivity, for example, metal and the image sensor 500 may directly contact a surface of the first groove 201 to expect an effect of discharging heat generated during an operation.

In this case, the second groove 202 may have a cross shape, but is not particularly limited thereto.

As illustrated in FIG. 17, the adhesive may be applied in the second groove 202.

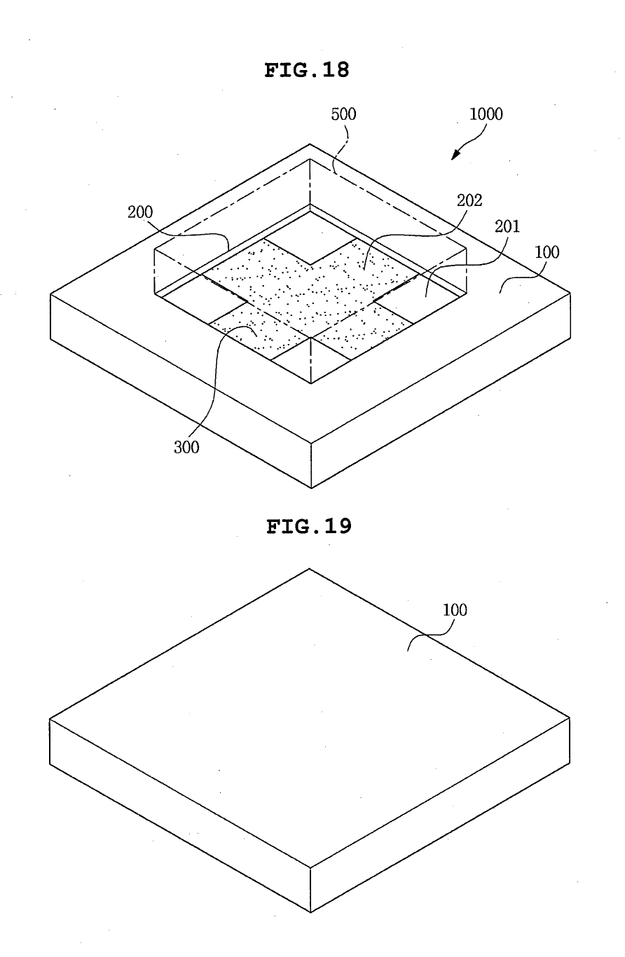

Referring to FIG. 18, the image sensor 500 may be surface-bonded with the first groove 201.

That is, the image sensor 500 on the adhesive 300 interposed in the second groove 202 is disposed in the groove 200 corresponding to the plane shape thereof to prevent warpage and distortion, thereby expecting the effect of improving the optical performance of the image sensor module.

FIGS. 19 to 22 are three-dimensionally exemplified diagrams sequentially illustrating a process of forming the image sensor mounted groove 200 of the base substrate 100 according to a third preferred embodiment of the present invention.

As illustrated in FIG. 19, first, the base substrate 100 is prepared.

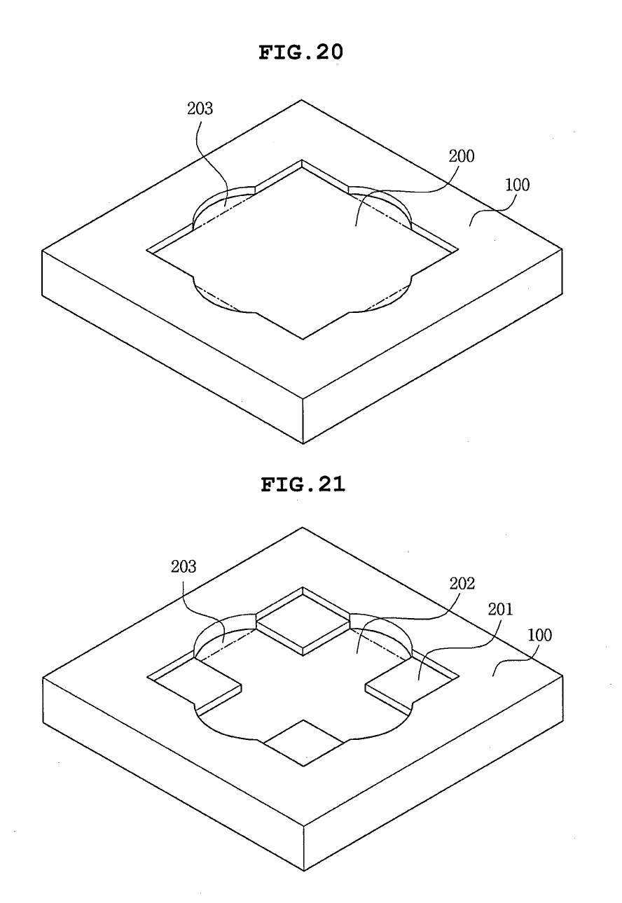

As illustrated in FIG. 20, a first method of machining the image sensor mounted groove 200 on the base substrate 100 may use a laser to perform laser trimming until the groove is generated, thereby forming a primary groove.

Further, as a second method, a photolithography method may be used.

In this case, the groove 200 may be formed, including the protruding region 203.

As illustrated in FIG. 21, the machined primary groove may be secondarily machined by the etching method to form the first groove 201, the protruding region 203, and the second groove 202 having a stepped shape.

Further, the first groove 201 is made of a material having high thermal conductivity, for example, metal and the image sensor 500 may directly contact a surface of the first groove 201 to expect an effect of discharging heat generated during an operation.

In this case, the second groove 202 may have a cross shape, but is not particularly limited thereto.

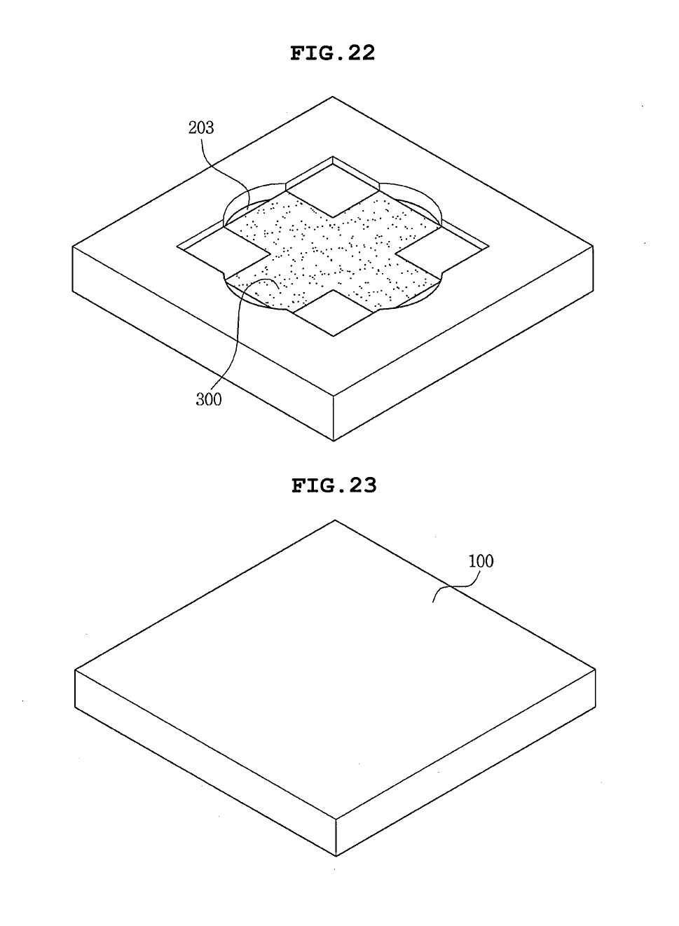

As illustrated in FIG. 22, the adhesive may be applied in the second groove 202.

The adhesive 300 applied in the second groove 202 may move to the protruding region 203 when the image sensor 500 contacts the surface of the first groove 201.

This is a space to prevent the adhesive 300 from overflowing to the outside of the groove 200, thereby improving the reliability of the image sensor module.

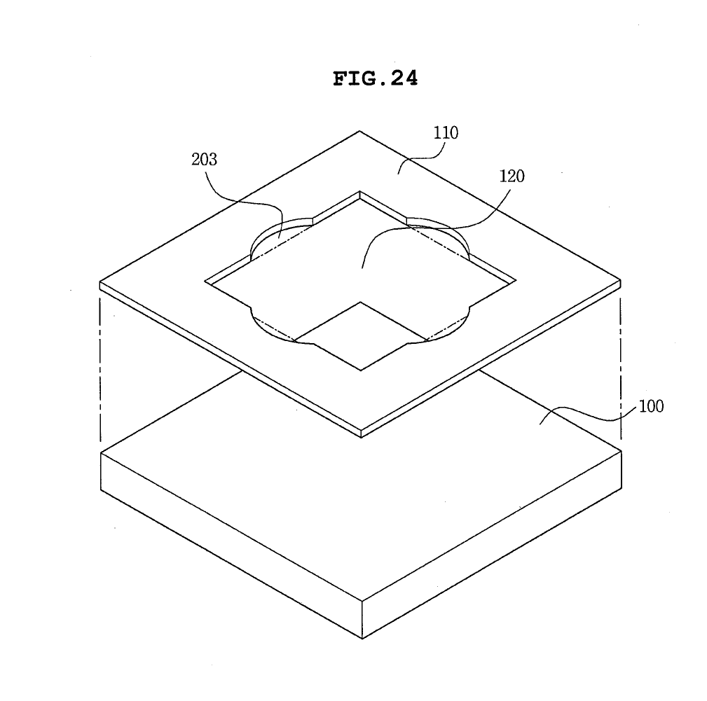

FIGS. 23 to 27 are three-dimensionally exemplified diagrams sequentially illustrating a process of forming the image sensor mounted groove 200 of the base substrate 100 according to a fourth preferred embodiment of the present invention.

As illustrated in FIG. 23, first, the base substrate 100 is prepared.

As illustrated in FIG. 24, an insulating layer 110 having a cavity 120 is prepared.

The cavity 120 may be formed by the method of patterning and punching the insulating layer 110.

In this case, the shape of the cavity 120 may be formed to correspond to the outside shape of the lower portion of the image sensor 500 and the protruding region 203 may be formed together.

Further, the insulating layer 110 having the cavity 120 may be stacked on the base substrate 100.

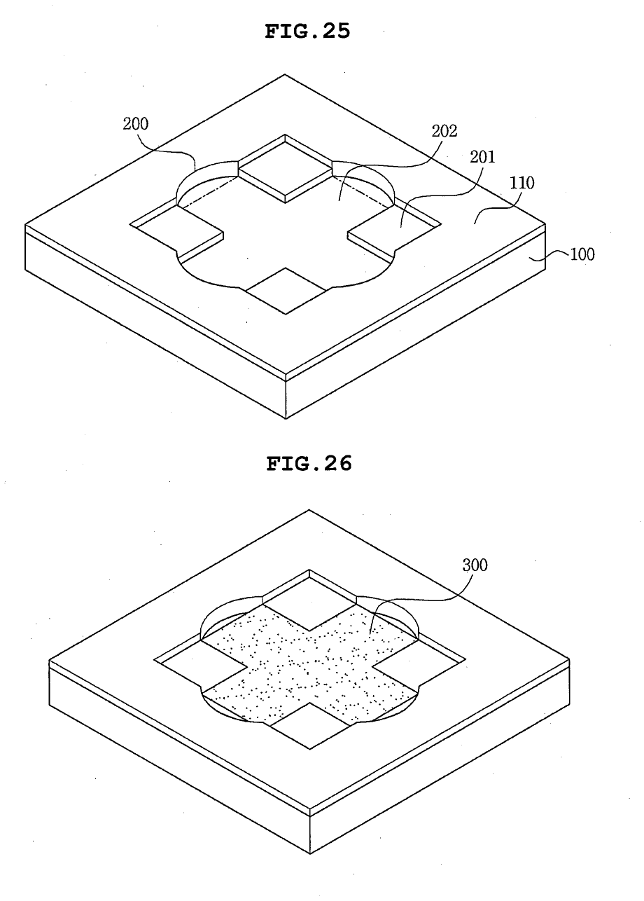

As illustrated in FIG. 25, the cavity 120 region of the stacked base substrate 100 may be machined by the etching method to form the image sensor mounted groove 200 having the first groove 201 and the second groove 202 having a stepped shape.

Further, the first groove 201 is made of a material having high thermal conductivity, for example, metal and the image sensor 500 may directly contact a surface of the first groove 201 to expect an effect of discharging heat generated during an operation.

In this case, the second groove 202 may have a cross shape, but is not particularly limited thereto.

As illustrated in FIG. 26, the adhesive may be applied in the second groove 202.

The adhesive 300 applied in the second groove 202 may move to the protruding region 203 when the image sensor 500 contacts the surface of the first groove 201.

This is a space to prevent the adhesive 300 from overflowing to the outside of the groove 200, thereby improving the reliability of the image sensor module.

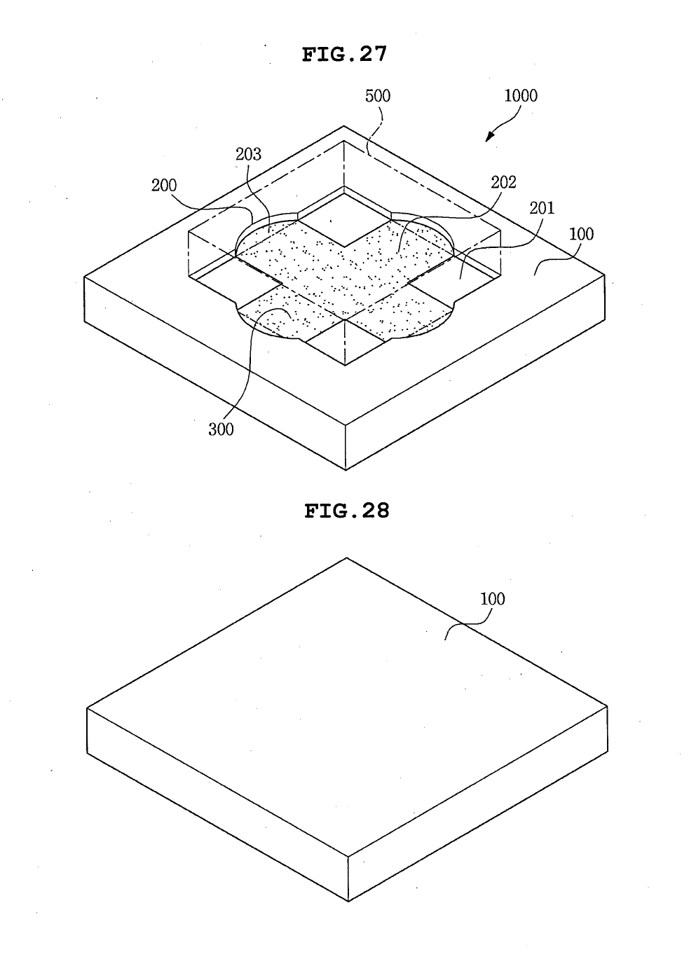

Referring to FIG. 27, the image sensor 500 may be surface-bonded with the first groove 201.

That is, the image sensor 500 on the adhesive 300 interposed in the second groove 202 is disposed in the groove 200 corresponding to the plane shape thereof to prevent warpage and distortion, thereby expecting the effect of improving the optical performance of the image sensor module.

FIGS. 28 to 31 are three-dimensionally exemplified diagrams sequentially illustrating a process of forming the image sensor mounted groove 200 of the base substrate 100 according to a fifth preferred embodiment of the present invention.

As illustrated in FIG. 28, first, the base substrate 100 is prepared.

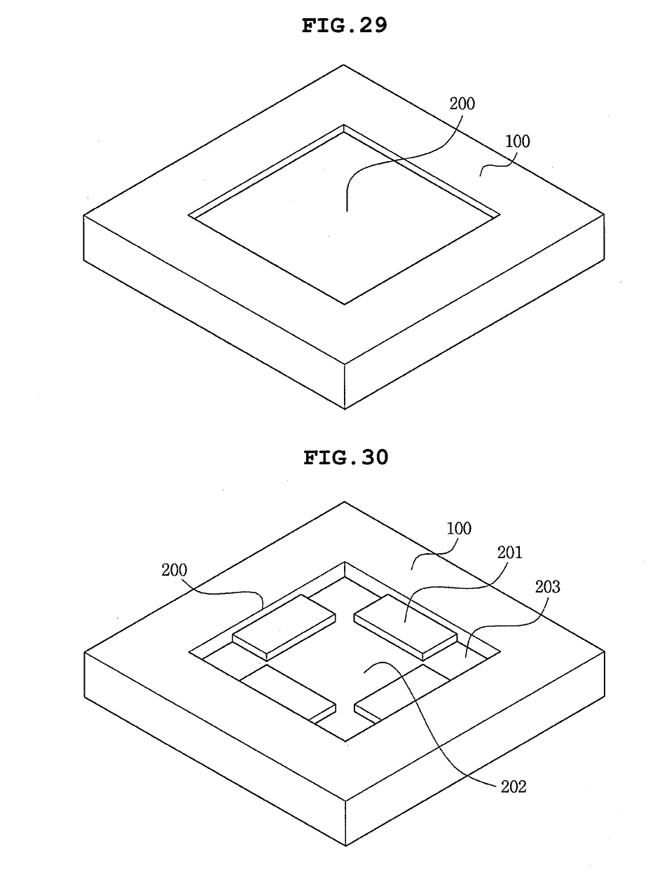

As illustrated in FIG. 29, a first method of machining the image sensor mounted groove 200 on the base substrate 100 may use a laser to perform laser trimming until the groove is generated, thereby forming a primary groove.

Further, as a second method, a photolithography method may be used.

In this case, the groove 200 may be formed, including the protruding region 203.

As illustrated in FIG. 30, the machined primary groove may be secondarily machined by the etching method to form the first groove 201, the protruding region 203, and the second groove 202 having a stepped shape.

Further, the first groove 201 is made of a material having high thermal conductivity, for example, metal and the image sensor 500 may directly contact a surface of the first groove 201 to expect an effect of discharging heat generated during an operation.

In this case, the second groove 202 may have a quadrangular shape, but is not particularly limited thereto.

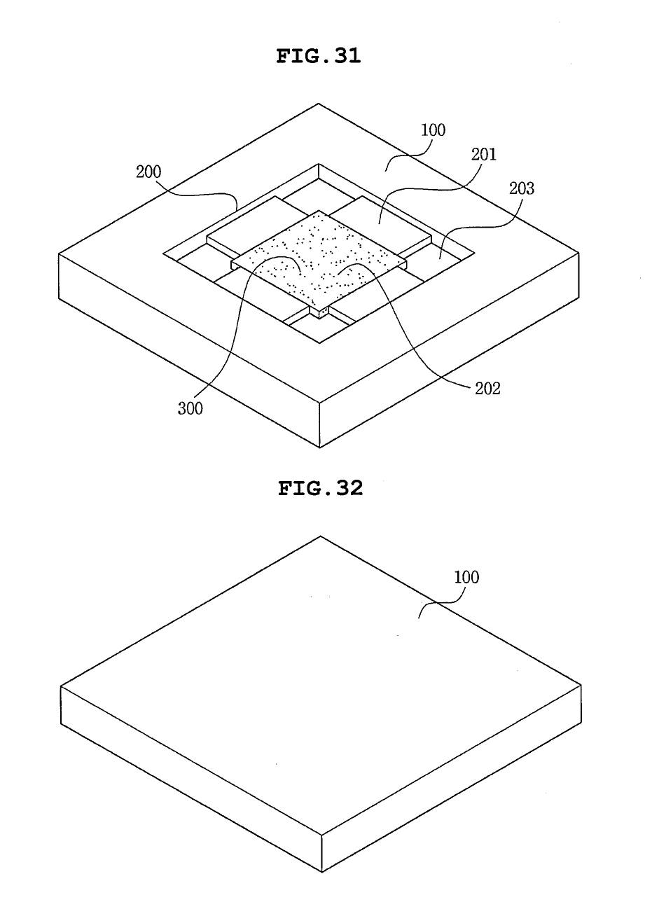

As illustrated in FIG. 31, the adhesive may be applied in the second groove 202.

The adhesive 300 applied in the second groove 202 may move to the protruding region 203 when the image sensor 500 contacts the surface of the first groove 201.

This is a space to prevent the adhesive 300 from overflowing to the outside of the groove 200, thereby improving the reliability of the image sensor module.

FIGS. 32 to 36 are three-dimensionally exemplified diagrams sequentially illustrating a process of forming the image sensor mounted groove 200 of the base substrate 100 according to a sixth preferred embodiment of the present invention.

As illustrated in FIG. 32, first, the base substrate 100 is prepared.

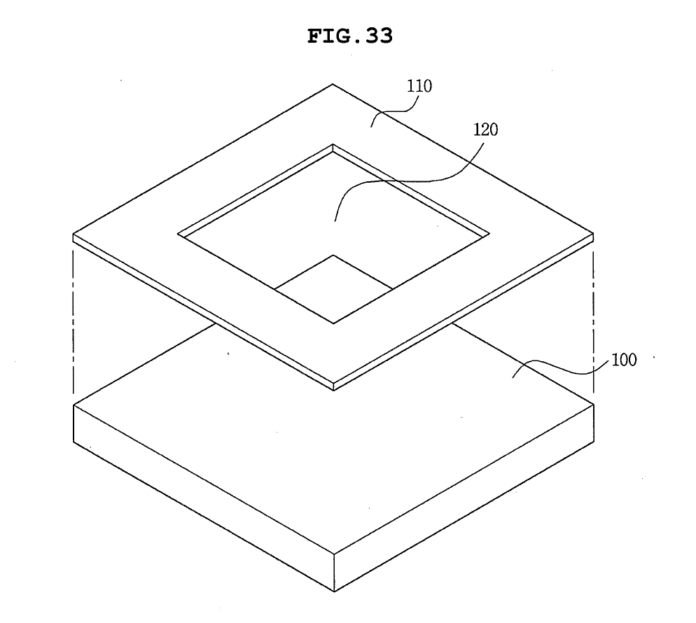

As illustrated in FIG. 33, an insulating layer 110 having a cavity 120 is prepared.

The cavity 120 may be formed by the method of patterning and punching the insulating layer 110.

In this case, the shape of the cavity 120 may be formed to correspond to the outside shape of the lower portion of the image sensor 500.

Further, the insulating layer 110 having the cavity 120 may be stacked on the base substrate 100.

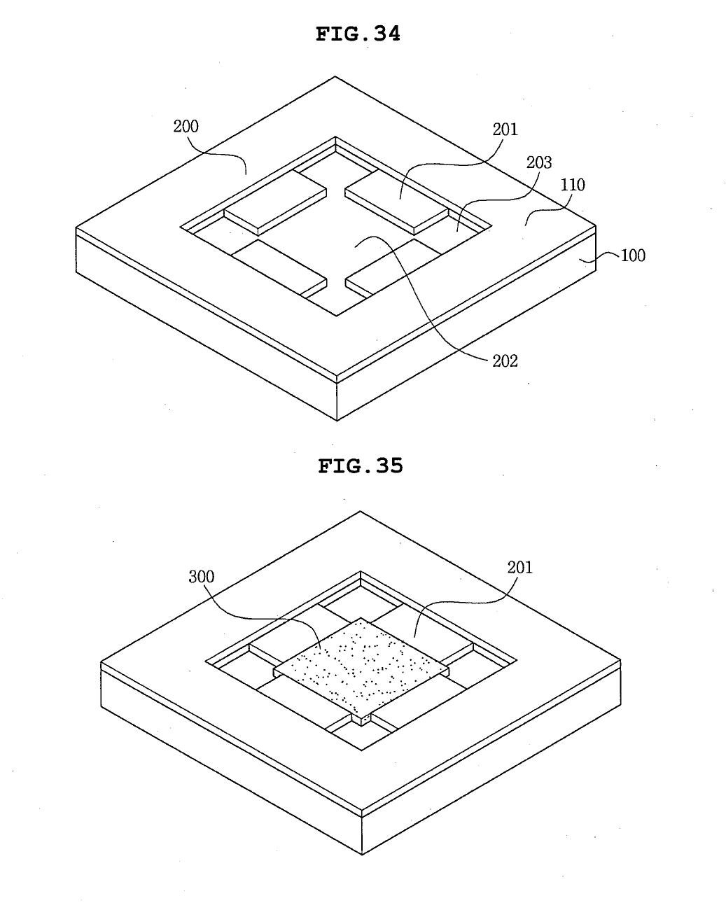

As illustrated in FIG. 34, the cavity 120 region of the stacked base substrate 100 may be machined by the etching method to form the image sensor mounted groove 200 having the first groove 201 and the second groove 202 having a stepped shape.

Further, the first groove 201 is made of a material having high thermal conductivity, for example, metal and the image sensor 500 may directly contact a surface of the first groove 201 to expect an effect of discharging heat generated during an operation.

In this case, the second groove 202 may have a quadrangular shape, but is not particularly limited thereto.

As illustrated in FIG. 35, the adhesive may be applied in the second groove 202.

The adhesive 300 applied in the second groove 202 may move to the protruding region 203 when the image sensor 500 contacts the surface of the first groove 201.

This is a space to prevent the adhesive 300 from overflowing to the outside of the groove 200, thereby improving the reliability of the image sensor module.

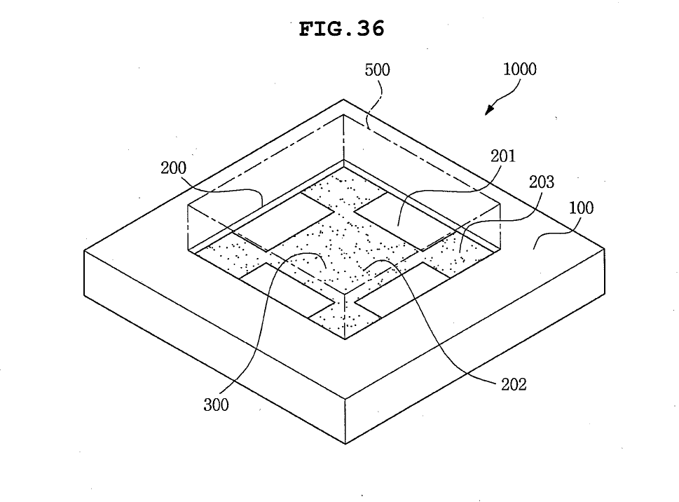

Referring to FIG. 36, the image sensor 500 may be surface-bonded with the first groove 201.

That is, the image sensor 500 on the adhesive 300 interposed in the second groove 202 is disposed in the groove 200 corresponding to the plane shape thereof to prevent warpage and distortion, thereby expecting the effect of improving the optical performance of the image sensor module.

According to the preferred embodiments of the present invention, the warpage and the distortion between the image sensor and the base substrate can be prevented by forming the double grooves on the base substrate, thereby improving the optical performance of the image sensor module.

Further, according to the preferred embodiment of the present invention, the overall thickness of the image sensor module can be reduced by embedding a part of the image sensor in the substrate.

Although the preferred embodiments of the present invention have been disclosed for illustrative purposes, they are for specifically explaining the present invention and thus a linear vibration motor according to the present invention are not limited thereto, but those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. An image sensor module, comprising:
a base substrate having an image sensor mounted groove including a first groove and a second groove having a stepped shape; and
an image sensor mounted in a groove of the base substrate.

2. The image sensor module as set forth in claim 1, wherein the image sensor is surface-contacted with the first groove and the second groove is filled with an adhesive.

3. The image sensor module as set forth in claim 1, wherein the second groove has a cross shape.

4. The image sensor module as set forth in claim 1, wherein the first groove is made of metal.

5. The image sensor module as set forth in claim 1, wherein a plane shape of the groove corresponds to a plane shape of a lower portion of the image sensor.

6. The image sensor module as set forth in claim 1, wherein the second groove has a protrusion protruding to an outside of the mounted image sensor.

7. A method of manufacturing an image sensor module, comprising:
preparing an image sensor mounted base substrate including a first groove and a second groove having a stepped shape;
applying an adhesive in the image sensor mounted groove; and
mounting the image sensor on the base substrate to which the adhesive is applied.

8. The method as set forth in claim 7, wherein the forming of the image sensor mounted groove includes:
preparing a base substrate;
machining a primary groove on the base substrate by a laser trimming process; and
forming an image sensor mounted groove having a first groove and a second groove having a stepped shape by secondarily machining the primary groove by an etching process.

9. The method as set forth in claim 7, wherein the forming of the image sensor mounted groove includes:
preparing a base substrate;
machining a primary groove on the base substrate by a photolithography process; and
forming an image sensor mounted groove having a first groove and a second groove having a stepped shape by secondarily machining the primary groove by an etching process.

10. The method as set forth in claim 7, wherein the forming of the image sensor mounted groove includes:
preparing a base substrate;
preparing an insulating layer having a cavity;
stacking the insulating layer on the base substrate; and
forming an image sensor mounted groove having the first groove and the second groove having a stepped shape by etching a cavity region of the base substrate on which the insulating layer is stacked.

11. The method as set forth in claim 7, wherein the second groove has a cross shape.

12. The method as set forth in claim 7, wherein the first groove is made of metal.

13. The method as set forth in claim 7, wherein a plane shape of the groove is formed to correspond to a plane shape of a lower portion of the image sensor.

14. The method as set forth in claim 7, wherein the second groove has a protrusion protruding to an outside of the mounted image sensor.
